(19) United States
(12) Patent Application Publication
(10) Pub. No.: US 2005/0046512 A1
(43) Pub. Date: Mar. 3, 2005

(54) Demultiplexer

(75) Inventors: Yoshikazu Kihara, Tokyo (JP); Masahiro Yamaki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 10/885,015

(22) Filed: Jul. 7, 2004

(30) Foreign Application Priority Data
Jan. 22, 2003 (JP) 2003-013985

(51) Int. Cl. H03H 9/72

(52) U.S. Cl. 333/133

(57) ABSTRACT

A demultiplexer includes a common terminal; a plurality of surface acoustic wave filters formed of surface acoustic wave devices, having signal terminals connected to the common terminal and having pass bands different from one another; and a phase shifter formed of a lumped constant element disposed between the common terminal and predetermined one of the surface acoustic wave filters having input impedance exerting influence on matching between impedance in the pass band of the predetermined surface acoustic wave filter viewed from the common terminal side and impedance viewed from the signal terminal side.

### BACKGROUND OF THE INVENTION

The present invention relates to a demultiplexer using a plurality of surface acoustic wave filters constituted by a plurality of surface acoustic wave elements formed on a piezoelectric substrate.

A surface acoustic wave filter composed of a plurality of surface acoustic wave elements formed on a piezoelectric substrate is known as a high-frequency band filter for use in a mobile communication appliance etc.

As this type surface acoustic wave filter, there is known a surface acoustic wave filter formed as a ladder-type circuit which has a series arm formed between an input terminal and an output terminal, a plurality of parallel arms formed between the series arm and a reference potential terminal, and surface acoustic wave resonators suitably disposed in the series arm and the parallel arms. There is also known a technique for forming a demultiplexer from a plurality of such ladder-type surface acoustic wave filters different inpass band frequency.

For example, a technique described in Japanese Patent No. 3,246,906 is known as the background art.

FIG. 23 is an equivalent circuit diagram showing a background-art demultiplexer. FIG. 24 is a graph showing frequency characteristic of the demultiplexer depicted in FIG. 23 in the neighbors of the pass bands. FIG. 25 is a graph showing frequency characteristic of the demultiplexer depicted in FIG. 23 in harmonic regions.

As shown in FIG. 23, a technique in which the common terminal C side initial stage of a first surface acoustic wave filter BF1 is provided as a T-input while the common terminal C side initial stage of a second surface acoustic wave filter BF2 is provided as a π-input so that a delay line 9 is used between the common terminal C and the second surface acoustic wave filter BF2 has been disclosed in Japanese Patent No. 3,246,906. Incidentally, a technique using an inductance element in place of the delay line 9 has been also disclosed in Japanese Patent No. 3,246,906.

According to this technique, it is said that a demultiplexer can be formed easily without much spoiling of original characteristic of the filters as shown in FIG. 24.

[Patent Document 1]

Japanese Patent No. 3,246,906

The demand for reduction in size and thickness of the demultiplexer per se and the demand for improvement in characteristic in the harmonic regions have increased in recent years.

Particularly, it is difficult to reduce the size of a demultiplexer using a frequency band of not higher than 1 GHz because of limitation in size and configuration of the surface acoustic wave elements.

When the delay line is used, a wavelength shortening effect based on the dielectric constant of the used dioelectric substrate can be obtained. For example, in a system using an 800 MHz band, the delay line however needs to have a length of about 40 mm when a glass epoxy board with a dielectric constant of about 4 is used, and the delay line needs to have a length of about 35 mm when a ceramic board with a dielectric constant of about 7 is used. Accordingly, it is very difficult to contain the delay line in a space smaller than 5 mm×5 mm while paying attention to crosstalk between delay lines and phase reduction.

Accordingly, when the aforementioned delay line is used for forming a demultiplexer, the demand for reduction in size and thickness cannot be satisfied because the shape of the demultiplexer is decided on the basis of the configuration size of the delay line.

The demand for attenuation of second, third and fourth harmonics of the reception filter has increased recently with the advance of direct conversion in an RF circuit portion of a mobile communication terminal. A phase shifter using the delay line which is a distributed constant line, however, does not effectively contribute to improvement in attenuation in the harmonic regions because the delay line is nothing but a distributed constant line so that the filter effect of the delay line per se is very low.

### SUMMARY OF THE INVENTION

Therefore, an object of the invention is to provide a demultiplexer in which reduction in size can be achieved and in which large attenuation can be obtained in other frequency bands than the pass bands.

To solve the problem, according to the invention, it is provided a demultiplexer having: a common terminal; a plurality of surface acoustic wave filters formed of surface acoustic wave devices, having signal terminals connected to the common terminal and having pass bands different from one another; and a phase shifter formed of a lumped constant element disposed between the common terminal and predetermined one of the surface acoustic wave filters having input impedance exerting influence on matching between impedance in the pass band of the predetermined surface acoustic wave filter viewed from the common terminal side and impedance viewed from the signal terminal side.

The invention is advantageous to reduction in size of the phase shifter per se made of a lumped constant element and advantageous to improvement in inter-element layout characteristic and reduction in size based on reduction in crosstalk and phase shortening caused by the approach between delay lines as a risk occurring when the delay lines are used. Accordingly, greater reduction in size can be achieved compared with a demultiplexer using a delay line.

Moreover, the phase shifter made of a lumped constant element is provided so that signal components in frequency bands other than the pass bands are attenuated by the phase shifter. Accordingly, large attenuation can be obtained in frequency bands other than the pass bands while reduction in size cane achieved. Accordingly, performance of the demultiplexer can be improved greatly.

### BRIEF DESCRIPTION OF THE DRAWINGS

FIG. 1 is an equivalent circuit diagram showing a demultiplexer according to an embodiment of the invention;

FIG. 2 is a graph showing input impedance characteristic of filters used in the demultiplexer depicted in FIG. 1;

FIG. 3 is a graph showing input impedance characteristic of the filters in a wide frequency band;

FIG. 4 is a graph showing input impedance characteristic of longitudinal double mode surface acoustic wave filters;

FIG. 5 is an exploded view showing a specific structure of the demultiplexer depicted in FIG. 1;

FIG. 6 is an explanatory view showing a modified example of an inductance element in the specific structure of the demultiplexer;

FIG. 7 is an explanatory view showing a modified example of capacitance elements in the specific structure of the demultiplexer;

FIG. 8 is a graph showing pass characteristic of a phase shifter using a lumped constant element in comparison with that of a delay line;

FIG. 9 is a graph showing phase characteristic of the phase shifter using a lumped constant element in comparison with that of the delay line;

FIG. 10 is a Smith chart showing impedance characteristic of the phase shifter using a lumped constant element in comparison with that of the delay line;

FIG. 11 is a graph showing frequency characteristic of the demultiplexer depicted in FIG. 1 in the neighbors of pass bands;

FIG. 12 is a graph showing frequency characteristic of the demultiplexer depicted in FIG. 1 in harmonic regions;

FIG. 13 is a Smith chart showing change in impedance of a second surface acoustic wave filter in the demultiplexer depicted in FIG. 1;

FIG. 14 is an equivalent circuit diagram showing a demultiplexer according to another embodiment of the invention;

FIG. 15 is a graph showing frequency characteristic of the demultiplexer depicted in FIG. 14 in the neighbors of pass bands;

FIG. 16 is a graph showing frequency characteristic of the demultiplexer depicted in FIG. 14 in harmonic regions;

FIG. 17 is an equivalent circuit diagram showing a demultiplexer according to a further embodiment of the invention;

FIG. 18 is an equivalent circuit diagram showing a demultiplexer according to a further embodiment of the invention;

FIG. 19 is a graph showing frequency characteristic of the demultiplexer depicted in FIG. 17 in the neighbors of pass bands;

FIG. 20 is a graph showing frequency characteristic of the demultiplexer depicted in FIG. 17 in harmonic regions;

FIG. 21 is a graph showing frequency characteristic of the demultiplexer depicted in FIG. 18 in the neighbors of pass bands;

FIG. 22 is a graph showing frequency characteristic of the demultiplexer depicted in FIG. 18 in harmonic regions;

FIG. 23 is an equivalent circuit diagram showing a background-art demultiplexer;

FIG. 24 is a graph showing frequency characteristic of the demultiplexer depicted in FIG. 23 in the neighbors of pass bands; and

FIG. 25 is a graph showing frequency characteristic of the demultiplexer depicted in FIG. 23 in harmonic regions.

### DETAILED DESCRIPTION OF THE PREFERRED EMBODIMENTS

An embodiment of the invention will be described specifically below with reference to the drawings. In the accompanying drawings, the same parts are denoted by the same reference numerals for the sake of omission of duplicated description. Although the embodiment of the invention is provided as a particularly useful embodiment for carrying out the invention, the invention is not limited to the embodiment.

The demultiplexer according to this embodiment is provided in such a manner that predetermined elements are formed on a piezoelectric substrate, for example, of LiTaO₃. That is, in FIG. 1, the demultiplexer has a common terminal C, a transmission filter (first surface acoustic wave filter) BF1, and a reception filter (second surface acoustic wave filter) BF2. Signal input/output is performed through the common terminal C. The transmission filter BF1 has one signal terminal t1 connected to the common terminal C through a junction J, and the other signal terminal t2 connected to a first signal terminal 1. The reception filter BF2 has one signal terminal t3 connected to the common terminal C through the junction J, and the other signal terminal t4 connected to a second signal terminal 2.

The transmission filter BF1 and the reception filter BF2 have such frequency characteristic that the pass band of one filter serves as the rejection band of the other filter. That is, the transmission filter BF1 and the reception filter BF2 have pass bands different from each other, and frequency characteristics different from each other. In this embodiment, the pass band of the reception filter BF2 is set to be higher than the pass band of the transmission filter BF1.

Although this embodiment shows the case where the pass band of the reception filter BF2 is higher than the pass band of the transmission filter BF1, the pass bands of the filters BF1 and BF2 may be set reversely. The piezoelectric substrate is not limited to the aforementioned example. For example, any suitable piezoelectric substrate such as a piezoelectric substrate of LiNbO₃ or a ceramic piezoelectric substrate may be used.

A phase shifter 6 made of a lumped constant element for attenuating signal components in frequency bands other than the pass band of the reception filter BF2 is disposed between the common terminal C and the reception filter BF2.

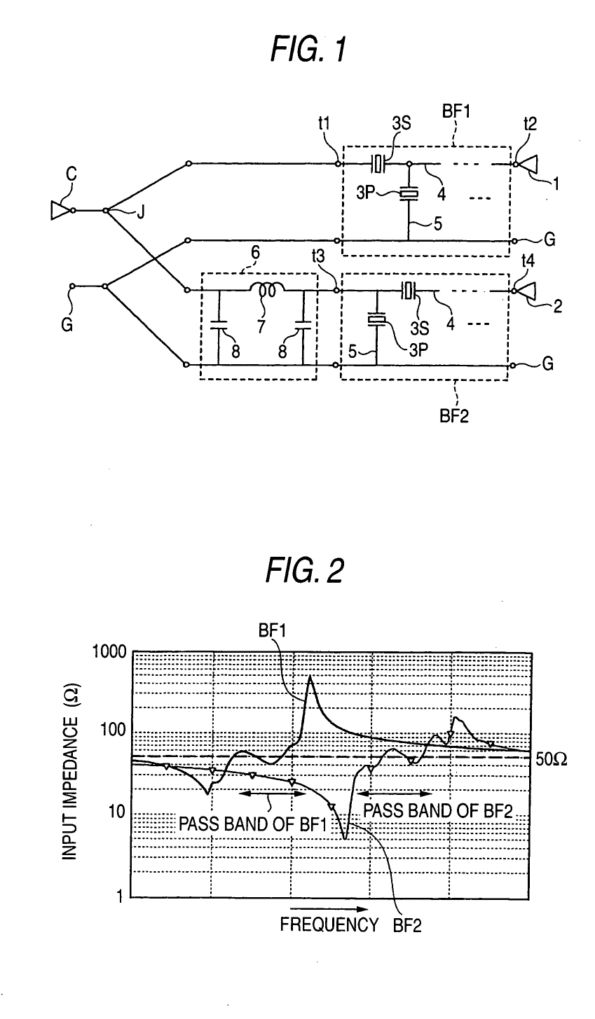

FIG. 2 shows impedance characteristic of the transmission filter BF1 viewed from the common terminal C side. The impedance of the transmission filter BF1 in the pass band of the reception filter BF2 is sufficiently higher than impedance, for example, of about 50 Ω which is input impedance in the pass band of the second surface acoustic wave BF2 and which is impedance viewed from the signal terminal t1 side. Even in the case where the two filters BF1 and BF2 are connected to the common terminal C as they are, the transmission filter BF1 has no influence on the second surface acoustic wave filter BF2 matched to impedance of the whole circuit in the pass band of the second surface acoustic wave filter BF2. That is, a demultiplexing function is achieved.

FIG. 2 also shows impedance characteristic of the reception filter BF2 viewed from the common terminal C side. The impedance of the reception filter BF2 in the pass band of the transmission filter BF1 exhibits a small value of about 15 Ω. When the two filters BF1 and BF2 are connected to the common terminal as they are, the impedance of the reception filter BF2 in the pass band of the first surface acoustic wave BF1 has influence on impedance characteristic of the transmission filter BF1. That is, the demultiplexing function is spoiled. It is therefore necessary to provide some impedance conversion means.

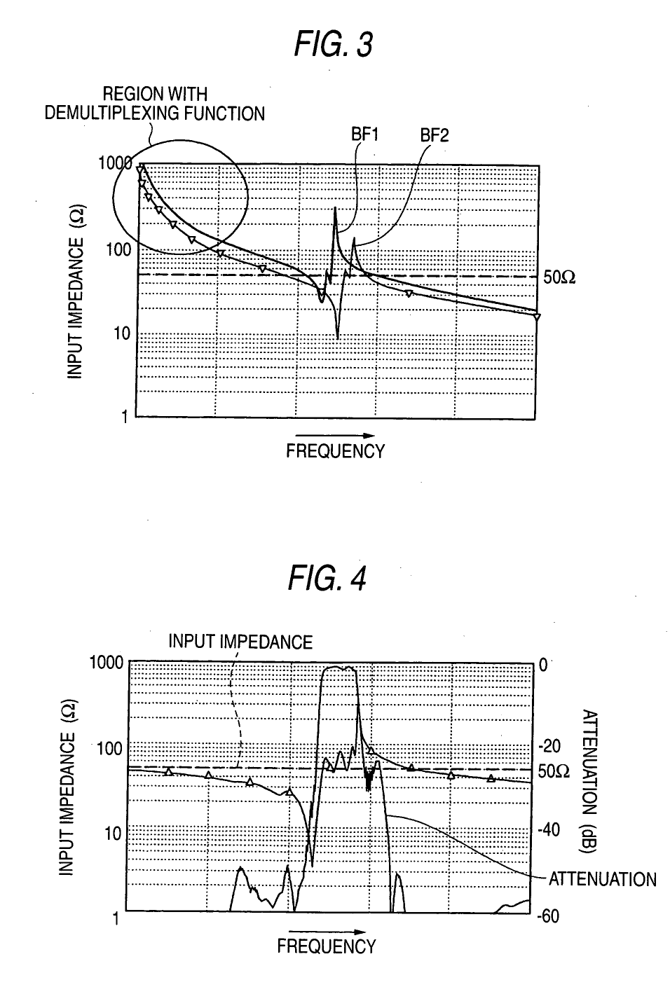

As described above, the demultiplexing function in the case where a plurality of filters are connected to the common terminal C is decided on the basis of input impedance of each filter viewed from the common terminal C side. That is, the demultiplexing function is not limited only by the configuration of filters. FIG. 3 shows an example of wide-band impedance characteristic of the transmission filter BF1 and the reception filter BF2 viewed from the common terminal C side. In FIG. 3, it is unnecessary to provide any phase shifter if the pass band of the transmission filter BF1 is located on a low frequency band side, because input impedance is increasing toward the low frequency side.

The same thing can be applied to the case where longitudinally coupled surface acoustic wave filters are used. FIG. 4 shows impedance characteristic of longitudinally coupled surface acoustic wave filters viewed from the common terminal side. Also in this case, the influence of impedance characteristic of one filter on impedance in the pass band of the other filter is decided on the basis of the position of the pass band of the other filter connected to the common terminal in the same manner as described above. Whether the demultiplexing function is present or not and the necessity of providing the phase shifter are decided. It is obvious that the same theory can be also applied to other mode coupling type surface acoustic wave filters, transversal surface acoustic wave filters, notch filters, etc.

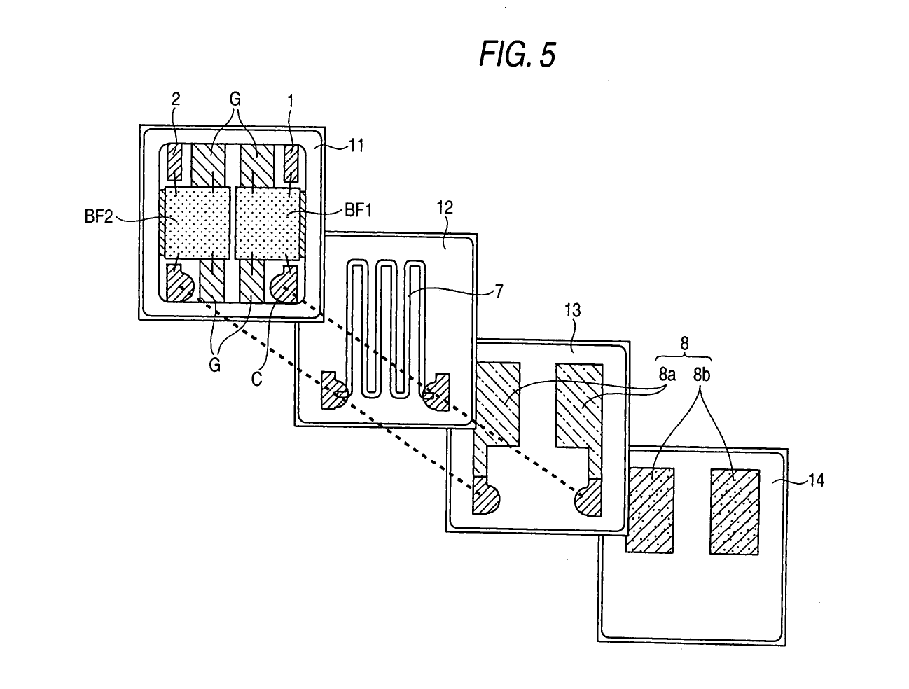

A specific structure of a small-size high-performance demultiplexer capable of demultiplexing the transmission filter and the reception filter connected to the common terminal C without use of any delay line will be described below with reference to FIG. 5.

For example, as shown in FIG. 5, the demultiplexer according to this embodiment is composed of boards formed as a four-layer structure. The respective boards are bonded to one another while aligned with one another. A transmission filter BF1, a reception filter BF2, a first signal terminal 1, a second signal terminal 2 and a reference potential terminal G are formed on and in the board 11 located as the uppermost layer.

Incidentally, a flip chip type filter mounted on the board 11 by means of face-down bonding or a wire-mount type filter mounted on the board 11 by bonding wires can be used as each of the transmission filter BF1 and the reception filter BF2. It is however preferable that a flip chip type filter is used from the point of view of high-density mounting and prevention of variation in frequency characteristic caused by inductance of bonding wires.

A phase shifter 6 made of a lumped constant element constituted by a π-low pass filter (LPF) is formed on the second-layer board 12, the third-layer board 13 and the fourth-layer board 14 provided as the lowermost layer. That is, an inductance element 7 made of a meander wiring pattern is formed on the board 12. Opposite ends of the inductance element 7 are electrically connected to the common terminal C and the reception filter BF2 on the board 11, respectively. Two electrode patterns 8a of capacitance elements 8 connected to the opposite ends of the inductance element 7 respectively are formed on the board 13. Two counter electrode patterns 8b opposite to the electrode patterns 8a through a predetermined gap are formed on the board 14.

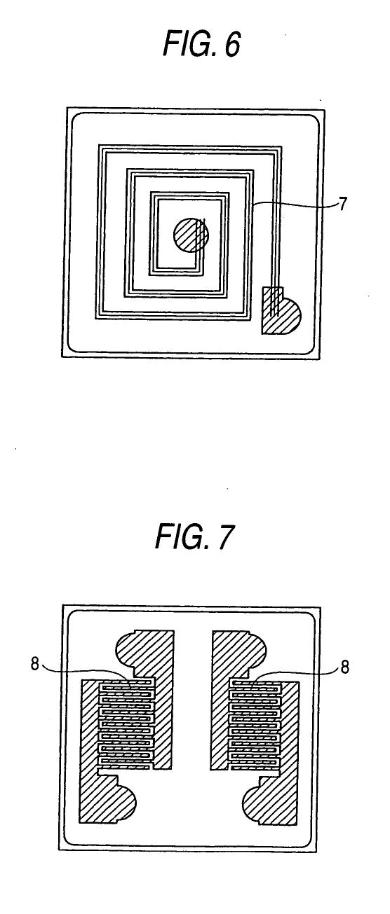

Incidentally, the patterns of the inductance and capacitance elements 7 and 8 are not limited to the example shown in FIG. 5. For example, the inductance element 7 may be shaped like a spiral as shown in FIG. 6, and the capacitance elements 8 may be shaped like comb electrodes as shown in FIG. 7.

The demultiplexer may not be formed three-dimensionally to have a laminated structure as shown in the drawings but may be formed two-dimensionally on a single plane.

In the description inclusive of the following description, the demultiplexer according to this embodiment is formed so that the phase shifter 6 using a lumped constant element is provided as one package including the transmission filter BF1 and the reception filter BF2. Alternatively, the phase shifter 6 may be provided as a so-called external type unit separated from the transmission filter BF1 and the reception filter BF2.

When expressed in a circuit diagram, the phase shifter 6 using a lumped constant element is a π-lowpass filter expressed as a π-equivalent circuit. That is, the low pass filter, which is the phase shifter 6 using a lumped constant element, includes an inductance element 7 disposed in a transmission line extending from the common terminal C, and two capacitance elements 8 disposed between the reference potential terminal G and opposite ends of the inductance element 7, respectively. In the description inclusive of the following description, the phase shifter 6 using a lumped constant element is composed of three elements. Alternatively, the phase shifter 6 may be composed of a desired number of elements such as five elements or seven elements.

The size of the lumped constant element can be reduced greatly compared with the size of the delay line using a distributed constant. Conventionally, the demultiplexer using a surface acoustic wave device was often composed of a delay line provided as a distributed constant element.

Characteristic impedance of the delay line is designed to be about 50 Ω which is input impedance of the surface acoustic wave device connected or drive impedance or load impedance of the device. Accordingly, the line width of the delay line needs to be set, for example, in a range of from 40 μm to 120 μm. Moreover, delay lines are laid out on the mount board so that a desired phase is achieved while a gap is provided between the delay lines to avoid lowering of characteristic impedance caused by coupling between the delay lines. Accordingly, a large mount area is required inevitably.

In the conventional art, the demultiplexer using the delay line was used in a band range of from an 800 MHz band to a 2 GHz band, so that the mount area was kept at a size of 5 mm×5 mm approximately. From the point of view of further reduction in size, it was however impossible to satisfy the sufficient reduction in size when the delay line was used.

On the other hand, the phase shifter is generally provided in the condition that the delay line can be little used in a lower frequency band such as an HF band or a VHF band. This is because it is difficult to actually form the delay line having a line length larger than 1 m on the circuit board. Use of the delay line is limited to the case where dimensional limitation is allowed. In most cases, the phase shifter using a lumped constant element is used in these frequency bands.

Therefore, the inventor has conceived that the same theory can be used for solving the problem for reduction in size of the demultiplexer. Although there has been never an example of configuration of the phase shifter using a lumped constant element in a micro-wave region, the phase shifter used in a surface acoustic wave device having a size of one hundred-thousandth as large as the wavelength of electromagnetic wave needs to have a remarkably small size correspondingly.

In the technique using the conventional delay line, it is however difficult to reduce the size of the delay line any more. Therefore, a lumped constant element is used in the configuration of the phase shifter in the demultiplexer using the surface acoustic wave device to attain further reduction in size.

An inductor, which is a lumped constant element, can obtain larger inductance as the width of each line becomes smaller. As the gap between lines becomes narrower, total inductance increases by inductance induced in the gap per se. Accordingly, use of the inductor is more advantageous to reduction in size than use of the delay line having a width limited by characteristic impedance. On the other hand, a capacitor is advantageous to reduction in size because the capacitance of the capacitor increases as the gap between opposite conductors of the capacitor decreases. The capacitor can be achieved easily by a laminated structure using a multilayer board. Accordingly, the inventor has conceived that the phase shifter using a lumped constant element is advantageous to reduction in size even in the case where increase in number of elements is considered.

Incidentally, a technique for forming a delay line from an inductor L as a lumped constant element has been described in claim 4 of Japanese Patent No. 3,246,906. Use of only the inductor is not sufficient. In any inductor range, impedance characteristic of a filter connected is shifted inductively in all bands inclusive of the pass band as well as other bands than the pass band. Accordingly, in a sufficiently matched filter, any part of matching characteristic definitely deteriorates. Accordingly, it is undesirable that the demultiplexer is formed from a circuit using only a series inductance element as described in Japanese Patent No. 3,246,906. It is more preferable that a matching reactance element is further provided.

In the invention, in consideration of this respect, the phase shifter is formed so that impedance of the phase shifter in a desired frequency can be sufficiently matched with load/drive impedance (e.g. a series inductor and parallel capacitors are disposed) and that a necessary phase rotation angle can be achieved in the desired frequency. Moreover, the phase shifter is disposed so that desired attenuation characteristic can be obtained in suppressed frequency bands other than the pass band by the effect of π- or T-impedance element filters achieved simultaneously.

The configuration of the phase shifter 6 to be inserted is given on the basis of input/output impedance Zlump in a desired frequency of the phase shifter, phase rotation angle γ and the number of elements. The simplest configuration using three elements is given by the expressions:
Zlump=(L/C)^{1/2}
γ=jω(L×C)^{1/2}
in which ω is a desired angular frequency.

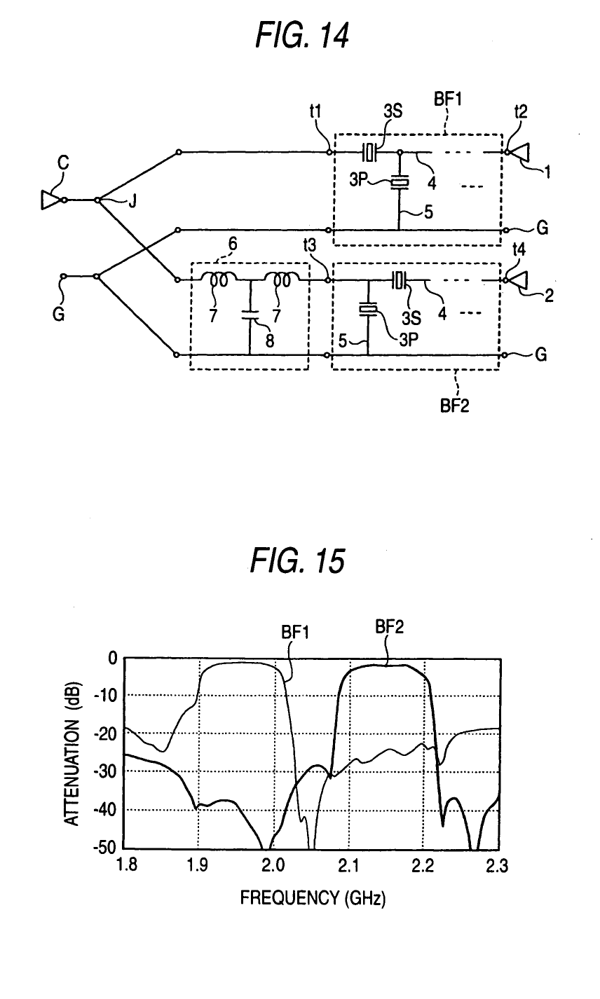

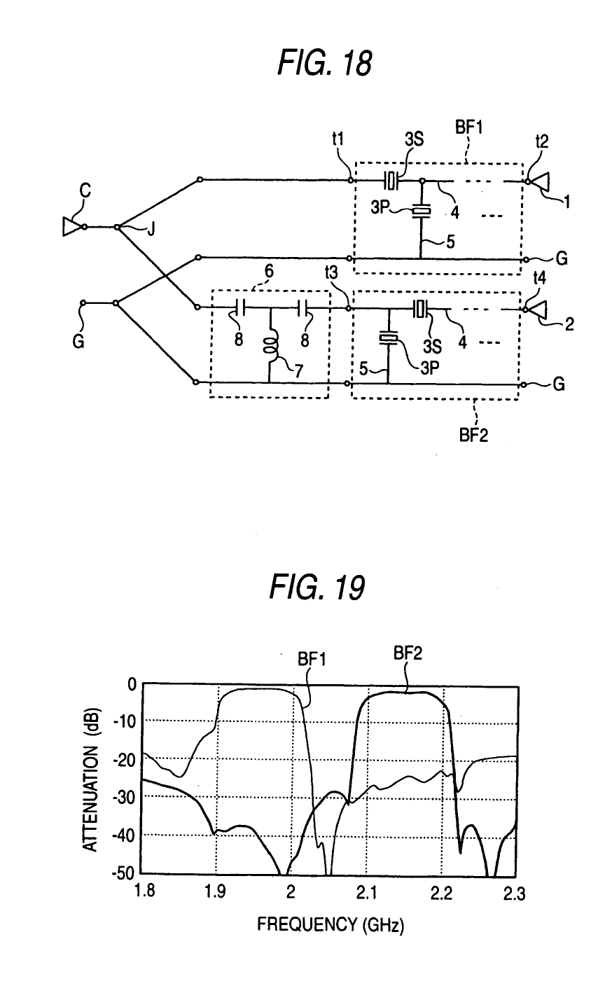

As the phase shifter using a lumped constant element, there can be provided four kinds of filters, that is, a T-low pass filter shown in FIG. 14, a π-low pass filter shown in FIG. 1, a π-high pass filter (HPF) shown in FIG. 17 and a T-high pass filter shown in FIG. 18. The contents of FIGS. 14, 17 and 18 will be described later.

All the element values of the four kinds of filters are given by the aforementioned expressions. The four kinds of filters are equal in impedance and phase rotation angle in the desired frequency band but different in transmission characteristic in the other frequency bands. The number of elements can be changed from three to five if elements are cascade-connected to collect the same element portions after calculation is made in the same manner as described above in the condition that a half value is given to γ.

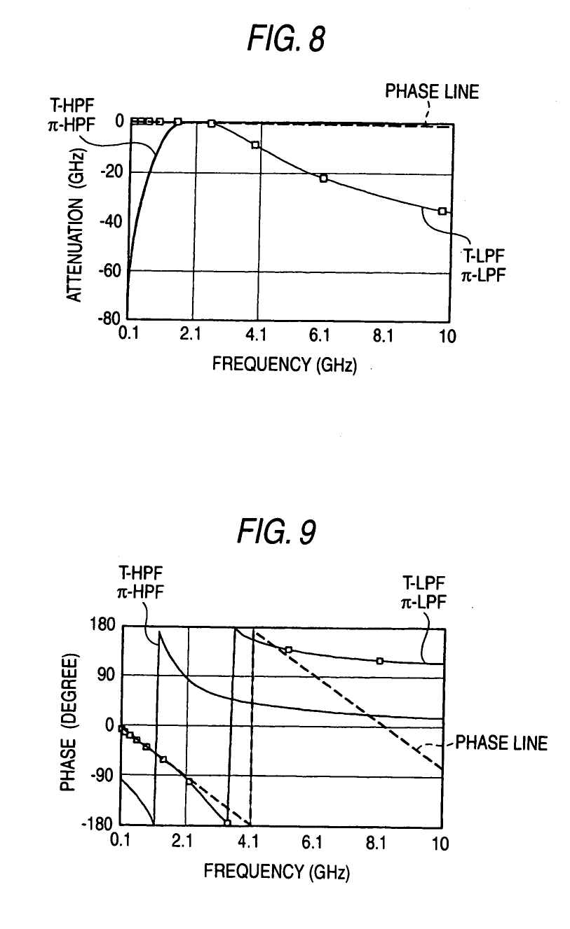

FIG. 8 shows pass characteristic of the phase shifters having the four kinds of configurations according to the invention in comparison with pass characteristic in a background-art device for a 2 GHz band. It is obvious that the pass characteristic in the background art changes with low loss in a range up to 10 GHz whereas the phase shifters having the four configurations of low pass filters and high pass filters according to the invention exhibit signal attenuation in higher and lower bands other than the desired frequency band.

FIG. 9 shows phase characteristic of the phase shifters having the four kinds of configurations according to the invention in comparison with phase characteristic in a background-art device for a 2 GHz band. It is obvious that each low pass filter gives the same phase as in use of the delay line in the desired frequency whereas each high pass filter gives the same phase as in use of the delay line in a frequency different from the desired frequency. Zlump and ω can be given at option in accordance with input/output impedance of each device and load/drive impedance of the device on the basis of setting of L and C.

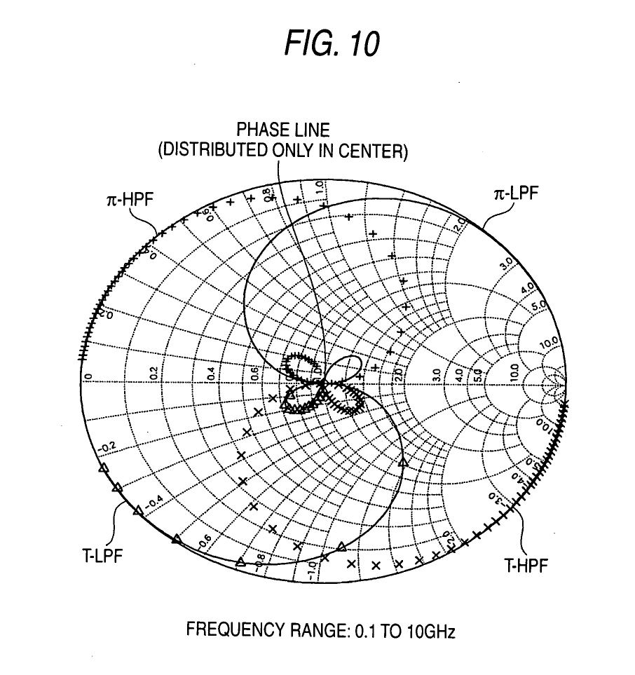

FIG. 10 is a Smith chart of impedance characteristic of the four kinds of phase shifters according to the invention. In the background art, the delay line exhibits transmission characteristic matched with load/drive impedance in a wide band. On the other hand, the phase shifters according to the invention have reflection coefficients largely different from one another in frequency bands other than the desired frequency band.

As described above, the phase shifters according to the invention are characterized in that diversified transmission characteristic, diversified phase characteristic and diversified impedance characteristic can be provided in frequency bands other than the desired frequency band in comparison with those in the case where the delay line is used. Accordingly, while impedance characteristic and phase characteristic of the phase shifter can be satisfied in the desired frequency band, transmission characteristic can be changed in frequency bands other than the desired frequency band.

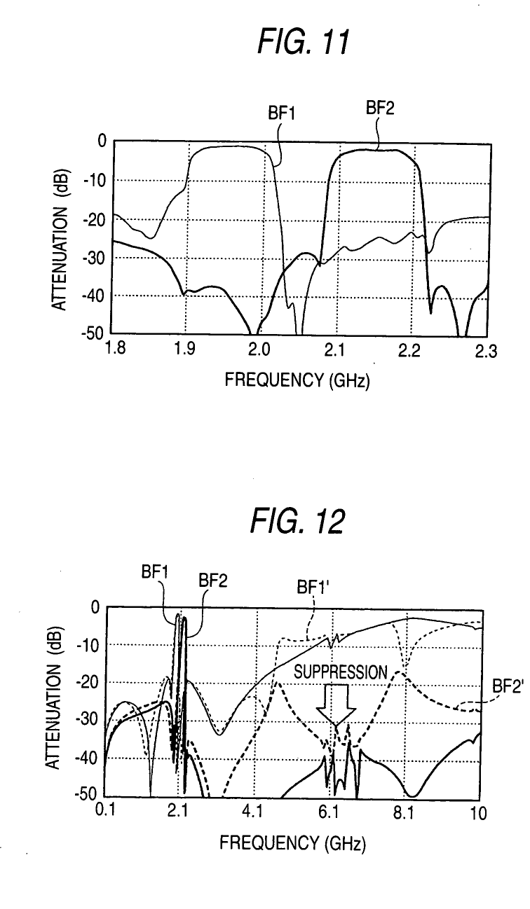

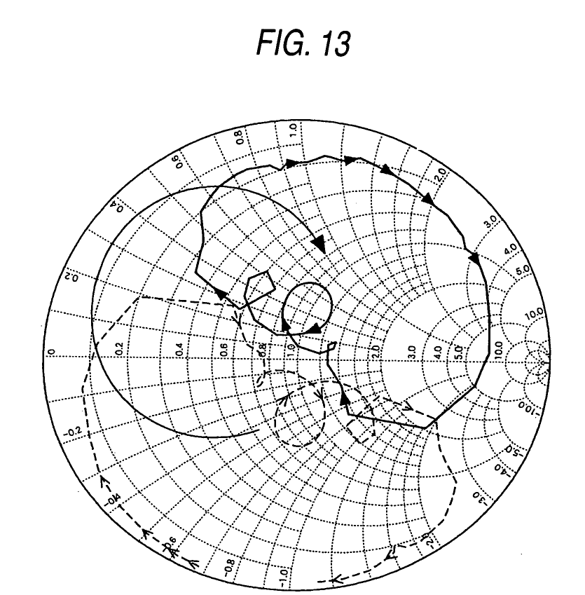

FIG. 11 shows frequency characteristic of the demultiplexer having the aforementioned structure in the neighbors of the pass bands. FIG. 12 shows frequency characteristic of the demultiplexer in harmonic regions. FIG. 13 shows a Smith chart of impedance characteristic of the reception filter BF2 provided on the reception side of the demultiplexer.

As shown in FIG. 11, the transmission filter BF1 and the reception filter BF2 have pass bands different from each other so that the pass band of the reception filter BF2 is higher than the pass band of the transmission filter BF1. As shown in FIG. 12, it is obvious that signal components in harmonic regions of the reception filter BF2 are intensively reduced compared with the case where the delay line is used (BF1′ and BF2′) because the phase shifter 6 using a lumped constant element acts on the signal components effectively. As shown in FIG. 13, it is obvious that impedance of the reception filter rotates clockwise to provide characteristic equivalent to that in use of the delay line though the lumped constant element is inserted and harmonic suppressing characteristic is obtained. As shown in FIG. 11, it is obvious that transmission characteristic in the pass band of BF1 is provided so as to be equivalent to that in the pass band of BF2.

When the demultiplexer is used, attenuation characteristic in harmonic regions of the reception filter can be improved to make it possible to reduce the size of the demultiplexer more greatly.

For example, a T-low pass filter expressed in a T-equivalent circuit as shown in FIG. 14 maybe used as the phase shifter 6 using a lumped constant element. That is, the low pass filter, which is the phase shifter 6 shown in FIG. 14, includes two inductor elements 7 disposed in a transmission line extending from the common terminal C, and a capacitance element 8 disposed between the midpoint of the inductance elements 7 and the reference potential terminal G.

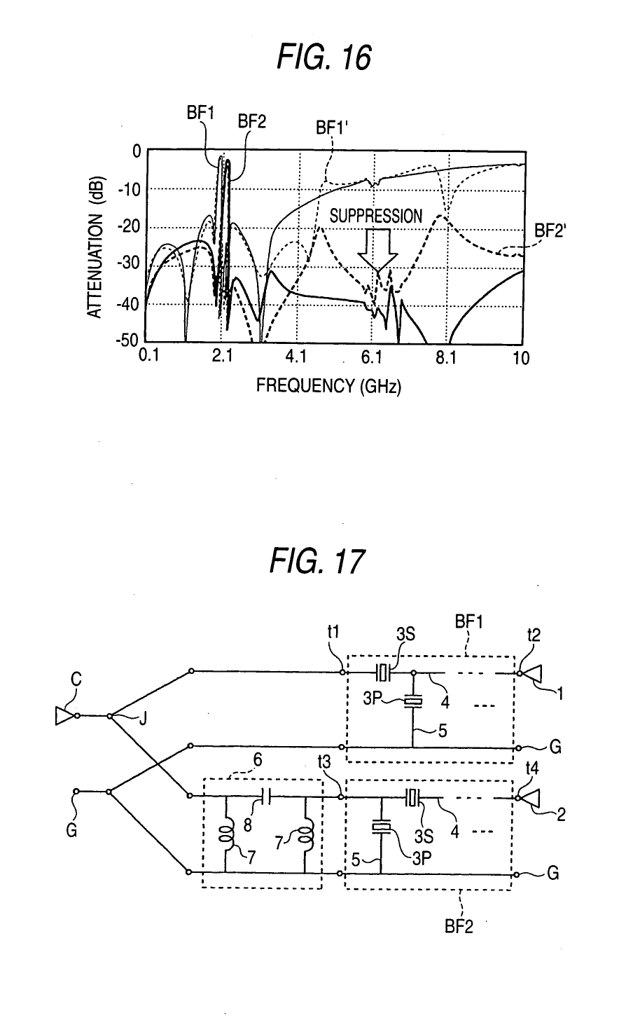

FIG.15 shows frequency characteristic of the phase shifter 6 shown in FIG. 14 in the neighbors of the pass bands. FIG. 16 shows frequency characteristic of the phase shifter 6 in harmonic regions. As shown in FIG. 15, the transmission filter BF1 and the reception filter BF2 have pass bands respectively so that the pass band of the reception filter BF2 is higher than the pass band of the transmission filter BF1. As shown in FIG. 16, it is obvious that signal components in harmonic regions of the reception filter BF2 are intensively reduced compared with the case where the delay line is used (BF1′ and BF2′).

A high pass filter such as a π-high pass filter expressed in a π-equivalent circuit as shown in FIG. 17 or a T-high pass filter expressed in a T-equivalent circuit as shown in FIG. 18 may be used as the phase shifter 6.

That is, the π-highpass filter, which is the phase shifter 6 shown in FIG. 17, includes a capacitance element 8 disposed in a transmission line extending from the common terminal C, and two inductance elements 7 disposed between the reference potential terminal G and opposite sides of the capacitance element 8, respectively.

On the other hand, the T-high pass filter, which is the phase shifter 6 shown in FIG. 18, includes two capacitance elements 8 disposed in a transmission line extending from the common terminal C, and an inductance element 7 disposed between the midpoint of the capacitance elements 8 and the reference potential terminal G.

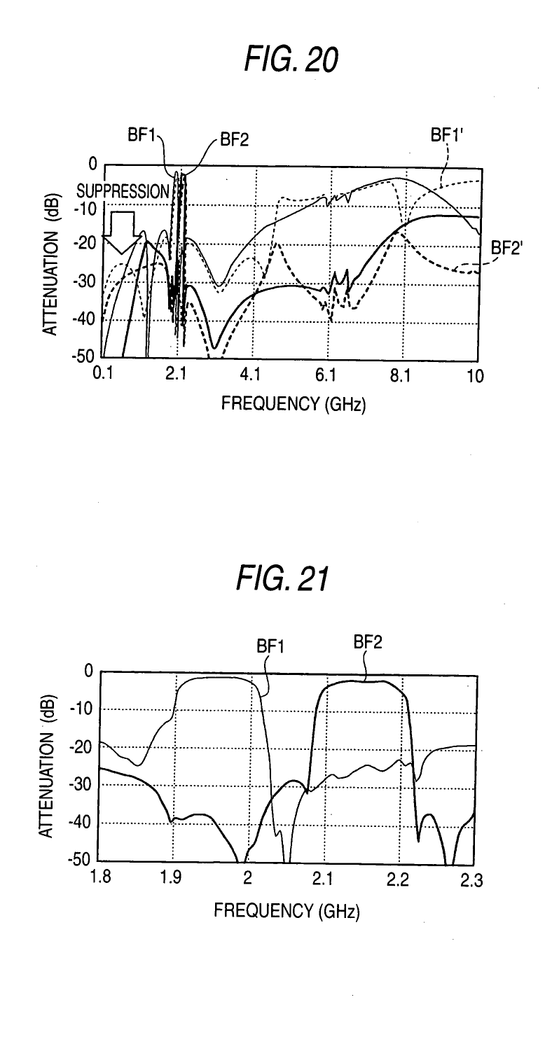

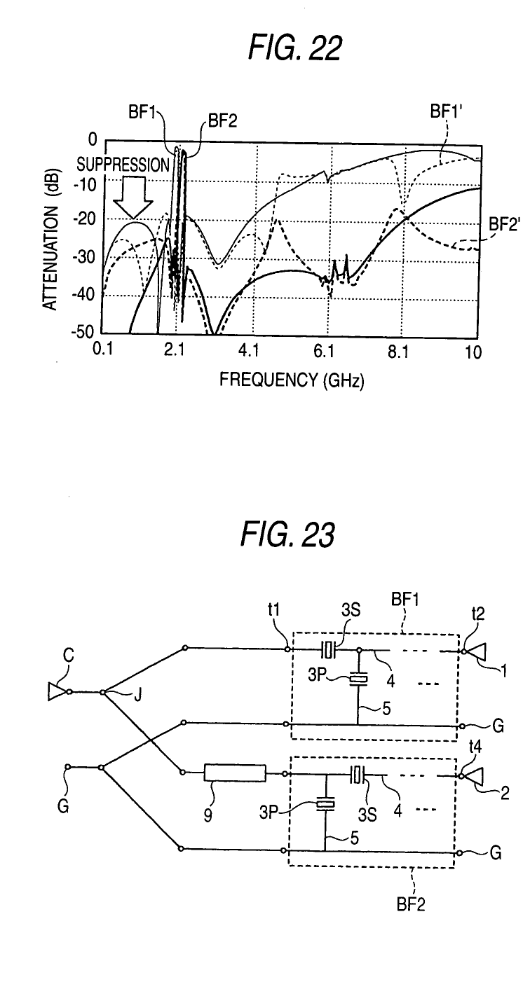

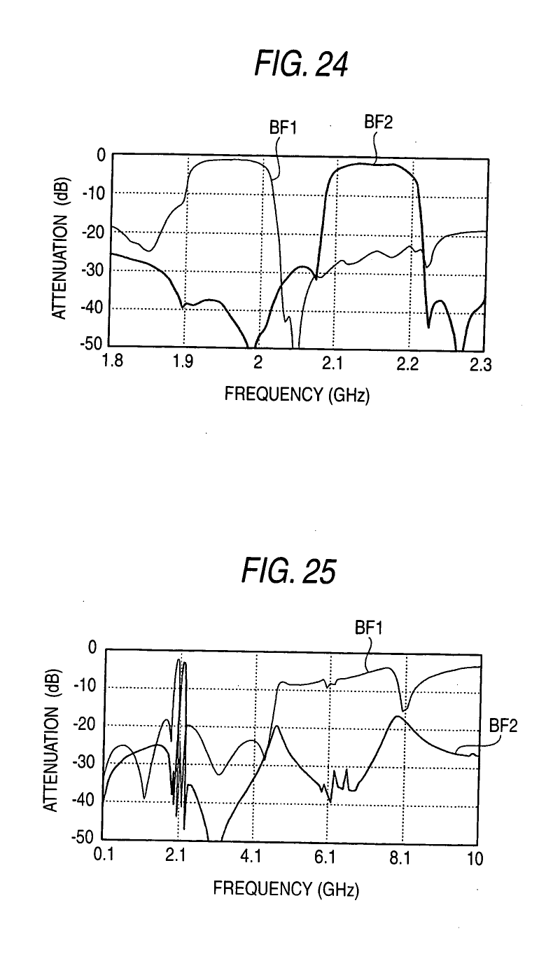

FIG. 19 shows frequency characteristic of the phase shifter 6 shown in FIG. 17 in the neighbors of the pass bands. FIG. 20 shows frequency characteristic of the phase shifter 6 shown in FIG. 17 in harmonic regions. FIG. 21 shows frequency characteristic of the phase shifter 6 shown in FIG. 18 in the neighbors of the pass bands. FIG. 22 shows frequency characteristic of the phase shifter 6 shown in FIG. 18 inharmonic regions.

As shown in FIGS. 19 and 21, the transmission filter BF1 and the reception filter BF2 have pass bands respectively so that the pass band of the reception filter BF2 is higher than the pass band of the transmission filter BF1. As shown in FIGS. 20 and 22, it is obvious that signal components in frequency bands (i.e. low frequency regions because the phase shifter 6 is the highpass filter) other than the passbands are intensively reduced compared with the case where the delay line is used (BF1′ and BF2′).

Each inductance element 7 grounded can provide surge voltage tolerance. Each capacitance element 8 inserted in series can cut off the DC component.

As described above, the phase shifter using a lumped constant element according to the invention can be used directly in place of the delay line in the background-art demultiplexer because the phase shifter can provide arbitrary input/output impedance and arbitrary phase quantity in a desired frequency band.

Although this embodiment has been described on the case where the demultiplexer includes two filters, the invention is not limited to the two-filter type demultiplexer and maybe also applied to a multi-filter type demultiplexer formed by any combination of a plurality of filters.

In the case of a multi-filter type demultiplexer, if input impedance of one of combined filters viewed from the common terminal side has influence on impedance in the pass band of another connected filter, the phase shifter 6 using a lumped constant element according to the invention may be inserted between the common terminal and the filter.

The phase shifter 6 provides desired impedance characteristic to the pass band of the filter. Impedance of the filter in the pass band of another connected filter is increased by the phase shifter, so that the influence of impedance of the filter on impedance in the pass band of another filter can be reduced.

As is obvious from the above description, the following effect can be obtained in accordance with the invention.

That is, the size of the demultiplexer according to the invention can be reduced because the phase shifter using a lumped constant element greatly excellent in space efficiency compared with a delay line or the like is used in the demultiplexer.

While desired impedance characteristic and phase characteristic of the demultiplexer can be provided in the pass bands of the filters, signal components can be attenuated in frequency bands other than the pass bands. Accordingly, both reduction in size and improvement in performance of the demultiplexer can be attained simultaneously.

When a high pass filter is used, a surge tolerance function and a DC cutting function can be added. Accordingly, multifunctionalization can be provided.

1. A demultiplexer comprising:
a common terminal;
a plurality of surface acoustic wave filters formed of surface acoustic wave devices, having signal terminals connected to said common terminal and having pass bands different from one another; and
a phase shifter formed of a lumped constant element disposed between said common terminal and predetermined one of said surface acoustic wave filters having input impedance exerting influence on matching between impedance in the pass band of said predetermined surface acoustic wave filter viewed from the common terminal side and impedance viewed from the signal terminal side.

2. A demultiplexer as claimed in claim 1, wherein said surface acoustic wave devices include:
a first surface acoustic wave filter formed of a surface acoustic wave device, having a signal terminal connected to said common terminal and having a predetermined pass band; and
a second surface acoustic wave filter formed of a surface acoustic wave device, having a signal terminal connected to said common terminal and having a pass band different from said pass band of said first surface acoustic wave filter.

3. A demultiplexer according to claim 2, wherein said first surface acoustic wave filter is formed in such a manner that a plurality of stages composed of series arm resonators made of surface acoustic wave resonators disposed in a series arm and parallel arm resonators made of surface acoustic wave resonators disposed in parallel arms are connected so that the first stage on the common terminal side is constituted by one of said series arm resonators; and
said second surface acoustic wave filter is formed in such a manner that a plurality of stages composed of series arm resonators made of surface acoustic wave resonators disposed in a series arm and parallel arm resonators made of surface acoustic wave resonators disposed in parallel arms are connected so that the first stage on the common terminal side is constituted by one of said parallel arm resonators.

4. A demultiplexer according to claim 1 or 2, wherein said phase shifter is a low pass filter.

5. A demultiplexer according to claim 4, wherein said low pass filter is a T-low pass filter expressed in a T-equivalent circuit.

6. A demultiplexer according to claim 5, wherein said low pass filter includes two inductance elements disposed in a transmission line extending from said common terminal, and a capacitance element disposed between the midpoint of said inductance elements and a reference potential terminal.

7. A demultiplexer according to claim 4, wherein said lowpass filter is a π-lowpass filter expressed in a π-equivalent circuit.

8. A demultiplexer according to claim 7, wherein said low pass filter includes an inductance element disposed in a transmission line extending from said common terminal, and two capacitance elements disposed between a reference potential terminal and opposite sides of said inductance element, respectively.

9. A demultiplexer according to claim 1 or 2, wherein said phase shifter is a high pass filter.

10. A demultiplexer according to claim 9, wherein said high pass filter is a T-high pass filter expressed in a T-equivalent circuit.

11. A demultiplexer according to claim 10, wherein said high pass filter includes two capacitance elements disposed in a transmission line extending from said common terminal, and an inductance element disposed between the midpoint of the capacitance elements and a reference potential terminal.

12. A demultiplexer according to claim 9, wherein said high pass filter is a π-high pass filter expressed in a π-equivalent circuit.

13. A demultiplexer according to claim 12, wherein said high pass filter includes a capacitance element disposed in a transmission line extending from said common terminal, and two inductance elements disposed between a reference potential terminal and opposite sides of said capacitance element, respectively.
